(19) United States
(12) Patent Application Publication
(10) Pub. No.: US 2010/0291728 A1
(43) Pub. Date: Nov. 18, 2010

(54) MANUFACTURING METHOD OF THE SOLAR CELL

(75) Inventors: Yun sung HUH, Anyang-Si (KR); Dong-soo KIM, Suwon-City (KR); Seung-II PARK, Cheonan-Si (KR); Man-Geun LEE, Daejeon (KR)

Correspondence Address: GIFFORD, KRASS, SPRINKLE,ANDERSON & CITKOWSKI, P.C, PO BOX 7021, TROY, MI, 48007-7021, US

(73) Assignee: SNT. CO., LTD, Hwaseong-City (KR)

(21) Appl. No.: 12/552,491

(22) Filed: Sep. 2, 2009

(30) Foreign Application Priority Data
May 15, 2009 (KR) 10-2009-0042507

(51) Int. Cl. H01L 31/0236

(52) U.S. Cl. 438/71; 438/72; 257/E31.13

(57) ABSTRACT

A method of manufacturing a solar cell, which can improve productivity by improving a surface texturing process for effectively capturing incident light during a process for manufacturing the solar cell, is provided. The method includes cleaning a substrate, texturing a surface of the substrate, doping and diffusing impurities into the substrate, coating an anti-reflection layer on the substrate, formed metal electrodes on the substrate, and cutting off corner electrodes among the metal electrodes. The texturing of the surface of the substrate includes printing a mask having a predetermined pattern on the substrate through an imprint process, etching the substrate, and removing the mask.

### CROSS-REFERENCE TO RELATED APPLICATION

This application claims priority to and the benefit of Korean Patent Application No. 10-2009-0042507 filed in the Korean Intellectual Property Office on May 15, 2009, the entire contents of which are incorporated herein by reference.

### BACKGROUND OF THE INVENTION

(A) Field of the Invention

The present invention relates to a method of manufacturing a solar cell. More particularly, the present invention relates to a method of manufacturing a solar cell, which can improve productivity by improving a surface texturing process for effectively capturing incident light during a process for manufacturing the solar cell.

(B) Description of the Related Art

Generally, a solar cell is a device for supplying electrical energy by absorbing light energy and generating, separating, and collecting charges (holes and electrons). That is, the solar cell has a semiconductor. Electron-hole pairs are generated in the semiconductor by the light introduced into the solar cell. In the electron-hole pairs, the electrons are transferred to an n-type semiconductor by an electric field generated in a p-n junction and the holes are transferred to a p-type semiconductor, thereby generating electrical power.

In order to improve the efficiency of the solar cell, surface texturing of a substrate has been used to maximize the absorption of the light. The surface texturing is generally performed through a photolithography process.

As shown in FIG. 9, a typical photolithography process S100 for the surface texturing includes coating a cleaned substrate with a photoresist (S101), baking the photoresist (S103), exposing the photoresist to ultraviolet rays (S105), hard-baking the photoresist (S107), developing the photoresist (S109), etching the photoresist (S111), and removing the photoresist (S113).

Such a photolithography process is time-consuming for the surface texturing of the substrate and increases the manufacturing cost. Therefore, the photolithography process is not appropriate for mass-production.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a method of manufacturing a solar cell having advantages of improving productivity by improving a surface texturing process for effectively capturing incident light during a process of manufacturing the solar cell.

In one exemplary embodiment of the present invention, the method includes cleaning a substrate, texturing a surface of the substrate, doping and diffusing impurities into the substrate, coating an anti-reflection layer on the substrate, formed metal electrodes on the substrate, and cutting off corner electrodes among the metal electrodes.

The texturing of the surface of the substrate may include printing a mask having a predetermined pattern on the substrate through an imprint process, etching the substrate, and removing the mask.

The printing of the mask may include printing the mask after applying a mask liquid to a mold on which the pattern is formed.

Alternatively, the printing of the mask may include applying a mask liquid to a surface of the surface, and allowing the mold on which the pattern is formed to contact the substrate.

The mask may be printed in a matrix pattern.

Alternatively, the mask may be printed in a pattern having a plurality of circular shapes spaced apart from each other at predetermined distances.

The mask may have a diameter or line widths of 0.05 μm-2 μm.

The mask may be formed of a photoresist.

Alternatively, the mask may be formed of an electron-beam resist.

The mold may be one of a flat-type mold or a roller-type mold.

The substrate may be formed of crystalline silicon.

According to the exemplary embodiment, the mass-production of the solar cells becomes possible by performing the surface texturing process using the imprint process during the manufacturing process of the solar cells, and thus the manufacturing process is simplified and the manufacturing cost can be reduced.

### BRIEF DESCRIPTION OF THE DRAWINGS

FIG. 1 is a flowchart illustrating a method of manufacturing a solar cell according to an exemplary embodiment of the present invention.

FIG. 2 is a diagram illustrating a surface texturing process according to an exemplary embodiment of the present invention.

FIG. 3 is a view of an apparatus used for performing the surface texturing process according to an exemplary embodiment of the present invention.

FIGS. 4 and 5 are views illustrating another exemplary embodiment of the present invention.

FIG. 6 is a view illustrating a substrate on which a matrix mask is printed according to an exemplary embodiment of the present invention.

FIG. 7 is a view illustrating a state where a substrate is surface-textured according to an exemplary embodiment of the present invention.

FIG. 8 is a view illustrating a substrate on which a mask is printed according to another exemplary embodiment of the present invention.

FIG. 9 is a flowchart illustrating a typical method of manufacturing a solar cell.

### DETAILED DESCRIPTION OF THE EMBODIMENTS

Exemplary embodiments of the present invention will hereinafter be described in detail referring to the drawings.

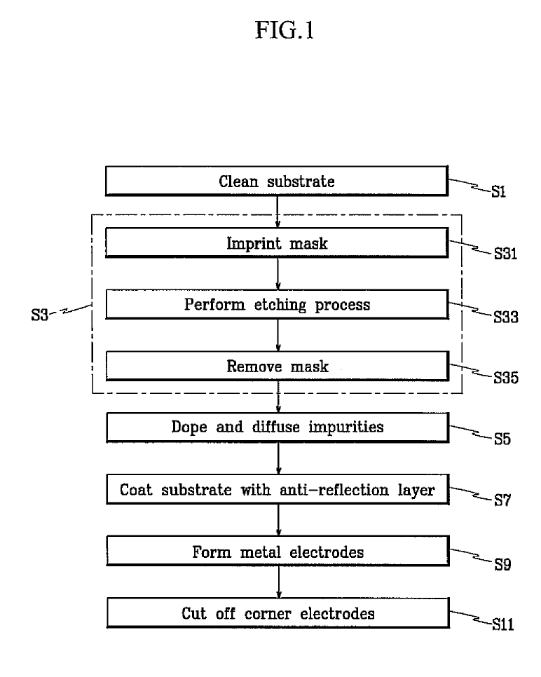

FIG. 1 is a flowchart illustrating a method of manufacturing a solar cell according to an exemplary embodiment of the present invention.

A method of manufacturing a solar cell according to an exemplary embodiment of the present invention includes cleaning a substrate (S1), texturing a surface of the substrate (S3), doping and diffusing impurities into the substrate (S5), coating the substrate with an anti-reflection layer (S7), forming a metal electrode on the substrate (S9), and cutting off a corner electrode (S11).

In one embodiment of the present invention, the substrate may be formed of crystalline silicon. However, the exemplary embodiment of the present invention is not limited to this. For example, a substrate that is used for a thin film type of silicon solar cell may be used in this exemplary embodiment.

The texturing of the surface of the substrate (hereinafter referred to as “surface-texturing”) S3 includes a mask imprinting process S31 and a mask removing process S35.

In the mask imprint process S31, a photoresist or electron-beam resist are printed on the substrate in a predetermined mask pattern.

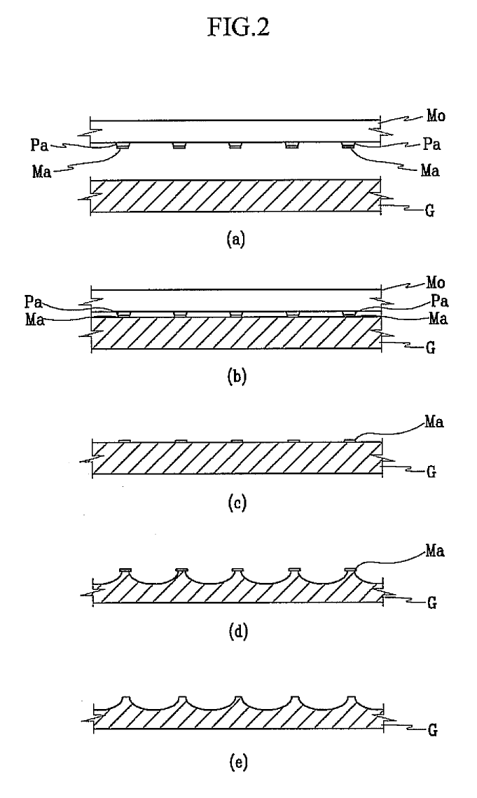

FIG. 2 is a view illustrating the imprint process S31. The following will describe the imprint process with reference to FIG. 2.

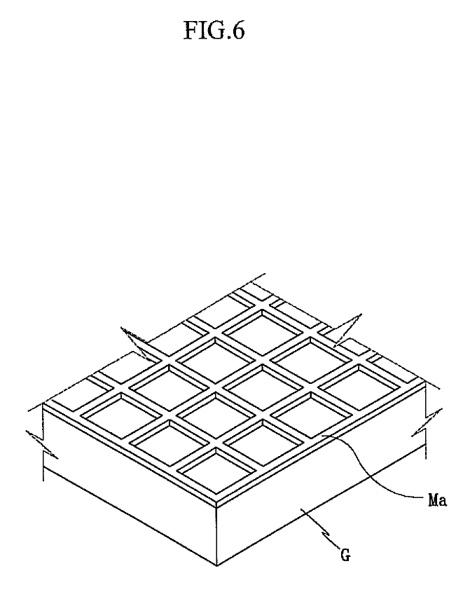

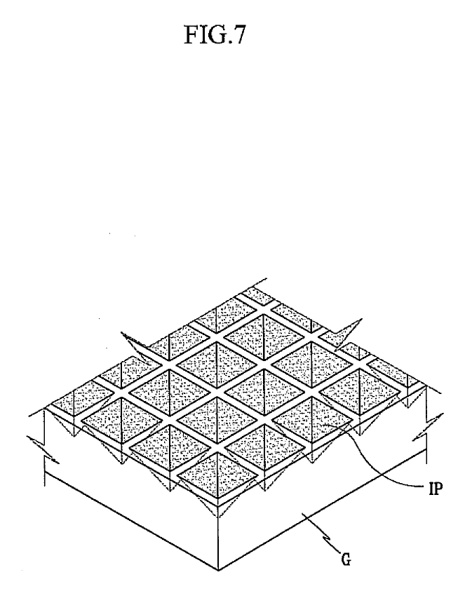

First, a predetermined pattern Pa is formed on a mold Mo. The pattern Pa protrudes in, for example, a matrix shape. In this exemplary embodiment, the reason for forming the pattern Pa on the mold Mo in the matrix pattern is that a mask (see FIG. 6) formed in the matrix shape is formed and thus a surface of the substrate G has an inverted pyramid shape IP (see FIG. 7) after etching.

When the surface of the substrate has the inverted pyramid shape IP, surface reflection loss can be reduced and the light absorption rate increases as the inverted pyramid shape IP confines the light. However, in the exemplary embodiment, the pattern of the mold for realizing the inverted pyramid shape of the surface of the substrate is not limited to the matrix pattern. That is, protruded circles or squares may be formed on the mold at a predetermined distance from each other so that the pyramid structure or a concavo-convex structure can be formed on the surface of the substrate after etching.

The mold Mo may be formed of a transparent or translucent synthetic resin. Alternatively, the mold Mo may be formed of an aqueous urethane material such as PDDP or a polydimethylsiloxane (PDMS) material. Particularly, since it is well known that the PDMS material has stable adhesive force, excellent formability and processability, and sufficient durability, it may be preferable that this material is used for the present exemplary embodiment.

A molten mask liquid is applied to a surface of the flat-type mold Mo on which the pattern is formed (see FIG. 2(a)). Next, the mold M is transferred such that the mask liquid adhered to the pattern pa of the mold M closely contacts the substrate G (see FIG. 2(b)). When the mold is detached from the substrate G, the mask liquid is printed on the substrate G.

At this point, the mask may be formed in the matrix pattern or the pattern having a plurality of circles spaced apart from each other at a predetermined distance. The mask may have a diameter or line width of 0.05 μm-2 μm. When the diameter or line width of the mask is out of the range, the light collecting efficiency may be deteriorated after the surface texturing process.

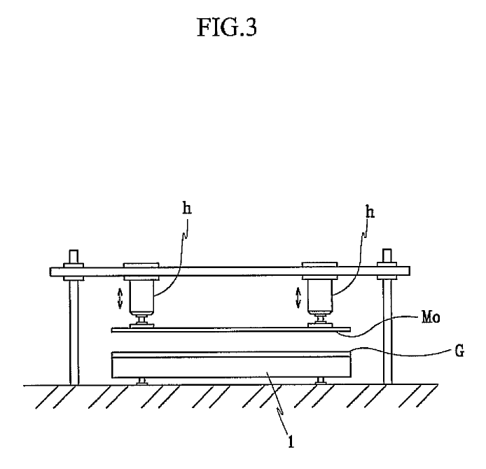

Meanwhile, FIG. 3 shows an apparatus for performing the mask imprint process. The apparatus includes a base 1 on which the substrate G is disposed, a mold Mo placed above the base 1 by a predetermined distance, and holders h that can fix the mold Mo and move the mold Mo in a vertical direction.

The apparatus for the imprint process enables the mold Mo to closely contact the substrate G or move away from the mold Mo by moving the mold in the vertical direction. However, the apparatus is not limited to the above-described structure and may be variously modified.

As described above, after the imprint process S31, an etching process is performed using an etchant (S33) (see FIG. 2(d)). At this point, as an undercut is realized in the etching process, a portion of an undersurface of the mask is etched. When it is difficult to texture the surface using wet-etching, dry-etching may be used to texture the surface. At this point, in the dry-etching, fluoride gas is injected to generate plasma.

In addition, after the etching process S33, the mask is removed (S35) (see FIG. 2(e)).

Further, after removing the mask (S35), impurities are doped and diffused (S5). After the above, an anti-reflection layer is coated (S7). The anti-reflection layer is a thin film for reducing light reflection loss on the surface of the solar cell. The anti-reflection layer may be formed of SiNx using a sputtering or plasma enhanced chemical vapor deposition (PECVD) apparatus.

After coating the anti-reflection layer (S7), metal electrodes are formed (S9). The metal electrodes may be formed on front and rear surfaces of the solar cell through a screen-printing process.

After coating the anti-reflection layer (S7), corner electrodes are cut off (S11). When a p-n junction is formed in the process for manufacturing the solar cell, the impurities are diffused to front, side, and rear surfaces. In addition, since a leakage current is generated at a portion where the metal is not deposited, there is a need to separate the p-n junction.

As described above, the exemplary embodiment of the present invention can significantly reduce the number of processes as compared with the photolithography process in the surface texturing process of the substrate.

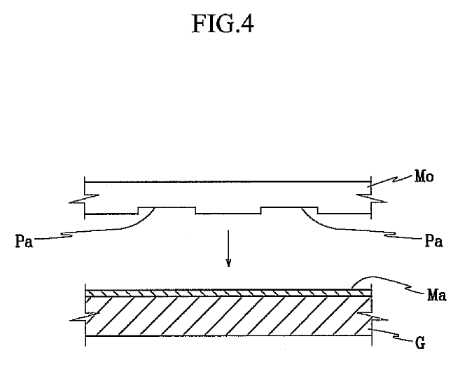

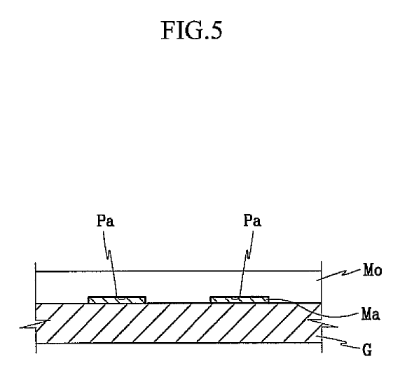

FIGS. 4 and 5 are views of a method for forming a mask on a substrate according to another exemplary embodiment of the present invention. In the forgoing exemplary embodiment, it is described that the printing is performed by allowing the mask liquid applied on the mold Mo to closely contact the substrate. However, in this exemplary embodiment, the mask liquid such as a photoresist is applied on a surface of the substrate and a mold on which a pattern Pa is formed is pressed on the substrate to form the mask Ma (see FIG. 5).

At this point, the mold may be formed in an intaglio pattern. The above-described exemplary embodiment shows that the present invention can be variously realized.

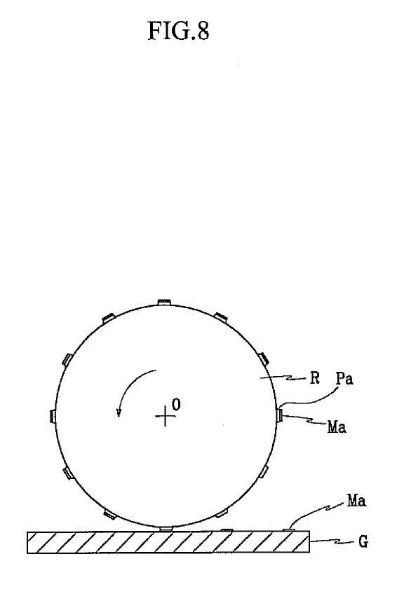

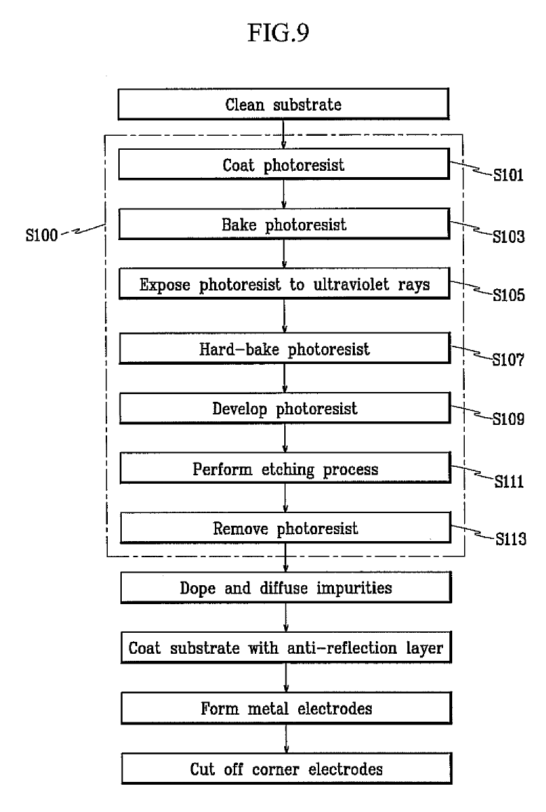

FIG. 8 is a view illustrating a case for imprinting a mask on a substrate using a roller-shaped mold according to another exemplary embodiment of the present invention. Only different points from the foregoing embodiment will be described in this exemplary embodiment. That is, in the foregoing embodiment, it is described that a flat-type mold is used in the surface texturing process for the substrate. However, in this exemplary embodiment, the mold for forming the mask is roller-shaped. That is, a protruded pattern is formed on an outer circumference of the roller-shaped mold and a mask liquid is applied on the mold, and the mask is imprinted on the substrate as the roller-shaped mold is rolled on the substrate.

This shows that the imprint process can be variously performed in the present invention.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A method of manufacturing a solar cell, comprising:
cleaning a substrate;
texturing a surface of the substrate;
doping and diffusing impurities into the substrate;
coating an anti-reflection layer on the substrate;
formed metal electrodes on the substrate; and
cutting off corner electrodes among the metal electrodes,
wherein the texturing of the surface of the substrate comprises:
printing a mask having a predetermined pattern on the substrate trough an imprint process;
etching the substrate; and
removing the mask.

2. The method of claim 1, wherein the printing of the mask comprises
printing the mask after applying a mask liquid on a mold on which the pattern is formed.

3. The method of claim 1, wherein the printing of the mask comprises:
applying mask liquid on a surface of the surface; and
allowing the mold on which the pattern is formed to contact the substrate.

4. The method of claim 1, wherein the mask is printed in a matrix pattern.

5. The method of claim 1, wherein the mask is printed in a pattern having a plurality of circular shapes spaced apart from each other by predetermined distances.

6. The method of claim 4, wherein the mask has a diameter or line widths of 0.05 μm-2 μm.

7. The method of claim 1, wherein the mask is formed of a photoresist.

8. The method of claim 1, wherein the mask is formed of an electron-beam resist.

9. The method of claim 2, wherein the mold is one of a flat-type mold or a roller-type mold.

10. The method of claim 1, wherein the substrate is formed of crystalline silicon.
